(19) United States
(12) Patent Application Publication
(10) Pub. No.: US 2012/0171421 A1
(43) Pub. Date: Jul. 5, 2012

(54) COATED ARTICLE AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/158,563

(22) Filed: Jun. 13, 2011

(30) Foreign Application Priority Data
Dec. 29, 2010 (CN) 201010612189.1

(51) Int. Cl. B32B 9/04; B32B 3/00; C23C 14/34; B32B 18/00; B32B 17/06; B32B 5/00; B32B 15/04

(52) U.S. Cl. 428/143; 428/696; 428/336; 428/469; 428/446; 428/432; 204/192.15

(57) ABSTRACT

A coated article is described. The coated article includes a substrate, and an anti-fingerprint film formed on the substrate. The anti-fingerprint film includes a non-crystalline alumina layer formed on the substrate and a non-crystalline aluminum-oxygen-fluorine layer formed on the non-crystalline alumina layer. The aluminum-oxygen-fluorine has a chemical formula of AlOₓF_{y}, wherein 0<x<1.5, 0<y<3. A method for making the coated article is also described.

### CROSS-REFERENCE TO RELATED APPLICATIONS

This application is one of the three related co-pending U.S. patent applications listed below. All listed applications have the same assignee. The disclosure of each of the listed applications is incorporated by reference into all the other listed applications.

| Attorney | | |
|---|---|---|
| Docket | | |
| No. | Title | Inventors |
| US 34930 | COATED ARTICLE AND METHOD | HSIN-PEI CHANG |
| | FOR MAKING THE SAME | et al. |
| US 34931 | COATED ARTICLE AND METHOD | HSIN-PEI CHANG |
| | FOR MAKING THE SAME | et al. |
| US 34932 | COATED ARTICLE AND METHOD | HSIN-PEI CHANG |
| | FOR MAKING THE SAME | et al. |

### BACKGROUND

1. Technical Field

The present disclosure relates to coated articles, particularly to a coated article having an anti-fingerprint property and a method for making the coated article.

2. Description of Related Art

Many electronic device housings are coated with anti-fingerprint film. These anti-fingerprint films are commonly painted on the housing as a paint containing organic anti-fingerprint substances. However, the printed film is thick (commonly 2 μm-4 μm) and not very effective. Furthermore, the printed film has a poor abrasion resistance, and may look oily. Additionally, the anti-fingerprint film may contain residual free formaldehyde, which is not environmentally friendly.

Therefore, there is room for improvement within the art.

### BRIEF DESCRIPTION OF THE FIGURES

Many aspects of the coated article can be better understood with reference to the following figures. The components in the figure are not necessarily drawn to scale, the emphasis instead being placed upon clearly illustrating the principles of the coated article. Moreover, in the drawings like reference numerals designate corresponding parts throughout the several views.

FIG. 1 is a cross-sectional view of an exemplary embodiment of a coated article.

FIG. 2 is a scanning electron microscopy (SEM) view of the coated article shown in FIG. 1.

FIG. 3 is an overlook view of an exemplary embodiment of a vacuum sputtering device.

### DETAILED DESCRIPTION

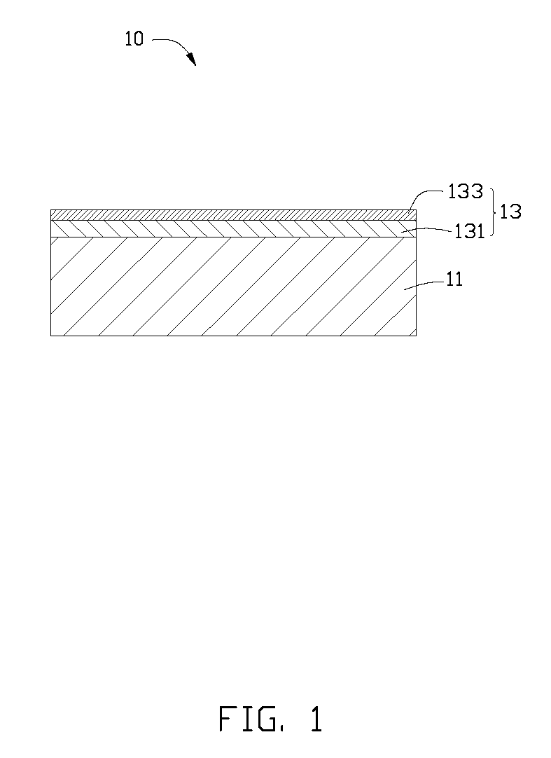

FIG. 1 shows a coated article 10 according to an exemplary embodiment. The coated article 10 includes a substrate 11, and an anti-fingerprint film 13 formed on a surface of the substrate 11.

The substrate 11 may be made of metal or non-metal material. The metal may be selected from a group consisting of stainless steel, aluminum, aluminum alloy, copper, copper alloy, and zinc. The non-metal may be ceramic or glass.

The anti-fingerprint film 13 includes a non-crystalline alumina (Al₂O₃) layer 131 formed on the substrate 11 and a non-crystalline aluminum-oxygen-fluorine (AlOₓF_{y}) layer 133 formed on the non-crystalline alumina layer 131. The anti-fingerprint film 13 may be formed by magnetron sputtering.

The Al₂O₃ layer 131 may have a nano-dimensioned non-crystalline structure. The thickness of the Al₂O₃ layer 131 may be about 450 nm-600 nm, which is relatively thin.

The AlOₓF_{y} layer 133 may have a nano-dimensioned non-crystalline structure. The value of ‘x’ within the AlOₓF_{y} may be between 0-1.5, that is 0<x<1.5. The value of ‘y’ within the AlOₓF_{y} may be between 0-3, that is 0<y<3.

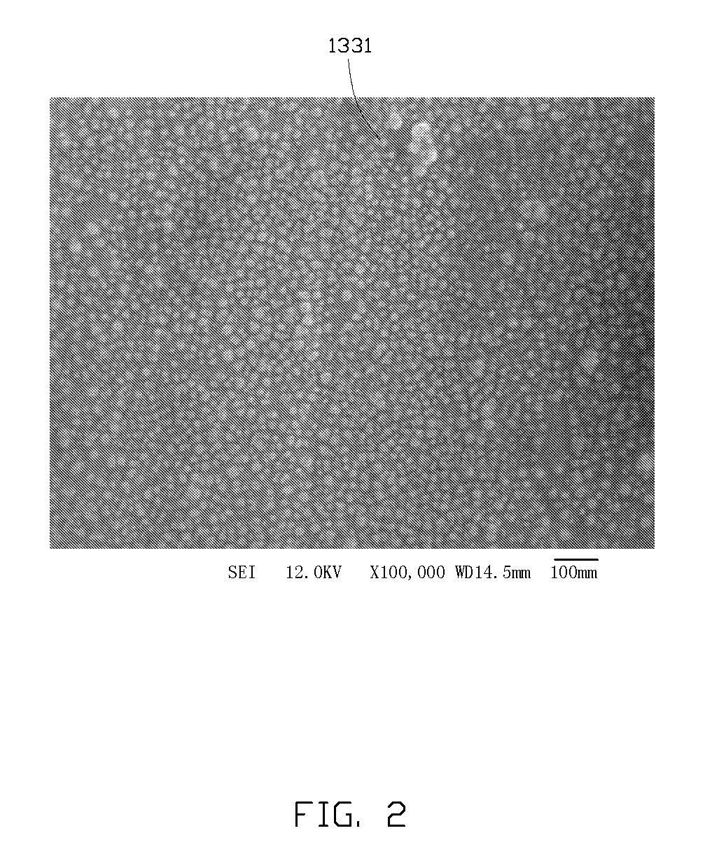

FIG. 2 shows a scanning electron microscopy (SEM) view of the coated article 10 with the AlOₓF_{y} layer 133 being scanned. FIG. 2 shows that the surface of the AlOₓF_{y} layer 133 defines with a plurality of nano-dimensioned protruding particles 1331. The nano-dimensioned protruding particles 1331 are evenly distributed on the surface of the AlOₓF_{y} layer 133. These nano-dimensioned protruding particles 1331 generate a plurality of nano-dimensioned pores (too small to be shown in FIG. 2). When water or oil droplets are on the surface of the AlOₓF_{y} layer 133, the nano-dimensioned pores will be sealed by the water or oil droplets and form a plurality of vapor locks. The vapor locks then attract and hold the water or oil droplet and prevent the water or oil droplet from spreading or distributing across the surface of the AlOₓF_{y} layer 133. As such, anti-fingerprint property of the anti-fingerprint film 13 is achieved.

The contact angle between the anti-fingerprint film 13 and water-oil droplet has been tested on the coated article 10. The contact angle is defined by an included angle between the surface of the anti-fingerprint film 13 and the tangent line of the water-oil droplet. The test indicates that the contact angle between the anti-fingerprint film 13 and the water-oil droplet is about 108°-112°. Thus, the anti-fingerprint film 13 has a good anti-fingerprint property.

Comparison with the painted anti-fingerprint layer shows that the anti-fingerprint film 13 of the current disclosure is tightly bonded to the substrate 11 and provides the coated article 10 with a good abrasion resistance.

It is to be understood that an aluminum transition layer may be set between the substrate 11 and the Al₂O₃ layer 131 to enhance the anti-fingerprint film 13 bonding to the substrate 11.

A method for making the coated article 10 may include the following steps:

The substrate 11 is pre-treated, such pre-treating process may include the following steps:

The substrate 11 is cleaned in an ultrasonic cleaning device (not shown) filled with ethanol or acetone.

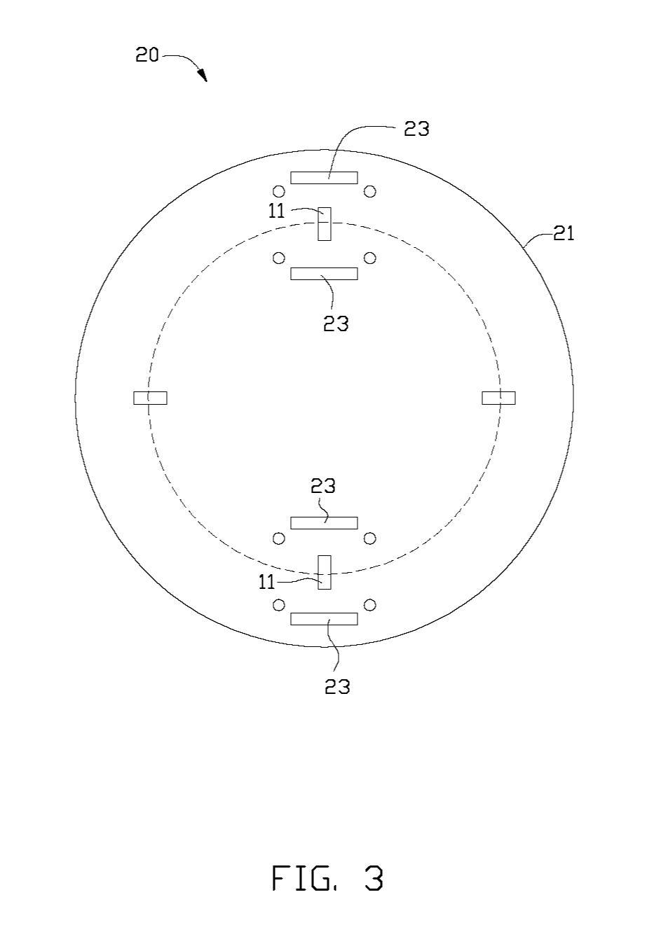

The substrate 11 is plasma cleaned. Referring to FIG. 3, the substrate 11 may be positioned in a coating chamber 21 of a vacuum sputtering device 20. The coating chamber 21 is fixed with aluminum targets 23 therein. The coating chamber 21 is then evacuated to about 4.0×10⁻³ Pa. Argon gas having a purity of about 99.999% may be used as a working gas and is injected into the coating chamber 21 at a flow rate of about 300 standard-state cubic centimeters per minute (sccm) to 500 sccm. The substrate 11 may be biased with negative bias voltage of about −300 V to about −500 V, then high-frequency voltage is produced in the coating chamber 21 and the argon gas is ionized to plasma. The plasma then strikes the surface of the substrate 11 to clean the surface of the substrate 11. Plasma cleaning the substrate 11 may take about 5 minutes (min) to 10 min. The plasma cleaning process enhances the bond between the substrate 11 and the anti-fingerprint film 13. The aluminum targets 23 are unaffected by the pre-cleaning process.

The Al₂O₃ layer 131 may be magnetron sputtered on the pretreated substrate 11 by using an intermediate frequency power for the aluminum targets 23. Magnetron sputtering of the Al₂O₃ layer 131 is implemented in the coating chamber 21. The inside of the coating chamber 21 is heated to about 150° C.-420° C. Oxygen (O₂) may be used as a reaction gas and is injected into the coating chamber 21 at a flow rate of about 200 sccm-500 sccm, and argon gas may be used as a working gas and is injected into the coating chamber 21 at a flow rate of about 300 sccm-500 sccm. The intermediate frequency power is then applied to the aluminum targets 23 fixed in the coating chamber 21, so the O₂ is ionized and chemically reacts with aluminum atoms which are sputtered off from the aluminum targets 23 to deposit the Al₂O₃ layer 131 on the substrate 11. The intermediate frequency power for the aluminum targets 23 may be of 5 kilowatt (KW)-10 KW. During the depositing process, the substrate 11 may be biased with negative bias voltage. The negative bias voltage may be about −150 V to about −300 V. Depositing of the Al₂O₃ layer 131 may take about 20 min-60 min.

The AlOₓF_{y} layer 133 may be magnetron sputtered on the Al₂O₃ layer 131 by using a radio frequency power for the aluminum targets 23. Magnetron sputtering of the AlOₓF_{y} layer 133 is implemented in the coating chamber 21. The inside of the coating chamber 21 maintained at about 150° C.-420° C. Oxygen (O₂) and carbon tetrafluoride (CF₄) may be used as reaction gases and are injected into the coating chamber 21. The O₂ has a flow rate of about 50 sccm-200 sccm. The CF₄ may have a partial pressure of 0.45 Pa-0.63 Pa in the coating chamber 21. Argon gas may be used as a working gas and is injected into the coating chamber 21 at a flow rate of about 300 sccm-500 sccm. The radio frequency power is then applied to the aluminum targets 23 at a power density of 50 watt per square centimeter (W/cm²) to 100 W/cm², so the O₂ and CF₄ are ionized to ‘O’ and ‘F’ and chemically react with aluminum atoms which are sputtered off from the aluminum targets 23 to deposit the AlOₓF_{y} layer 133 on the Al₂O₃ layer 131. During the depositing process, the substrate 11 may be biased with negative bias voltage of −150 V to about −300 V. Depositing of the AlOₓF_{y} layer 133 may take about 70 min-120 min.

In the exemplary embodiment, the AlOₓF_{y} layer 133 is formed after the forming of the Al₂O₃ layer 131, which prevents the ionized CF₄ from eroding the substrate 11 during forming the AlOₓF_{y} layer 133.

The AlOₓF_{y} layer 133 can also be formed by directly fluoridating the Al₂O₃ layer 131.

It is to be understood that before forming the non-crystalline Al₂O₃ layer 131, an aluminum transition layer may be formed on the substrate 11.

Specific examples of making the coated article 10 are described as following. The ultrasonic cleaning in these specific examples may be substantially the same as described above so it is not described here again. Additionally, the process of magnetron sputtering of the anti-fingerprint film 13 in the specific examples is substantially the same as described above, and the specific examples may mainly emphasize the different process parameters of making the coated article 10.

### Example 1

Plasma cleaning the substrate 11: the flow rate of Ar is 500 sccm; the substrate 11 has a negative bias voltage of −300 V; plasma cleaning of the substrate 11 takes 8 min.

Sputtering to form non-crystalline Al₂O₃ layer 131 on the substrate 11: the flow rate of Ar is 320 sccm, the flow rate of O₂ is 280 sccm; the substrate 11 has a negative bias voltage of −180 V; the aluminum targets 23 are applied with an intermediate frequency power of 10 KW; the temperature inside of the coating chamber 21 is 200° C.; sputtering of the Al₂O₃ layer 131 takes 40 min; the Al₂O₃ layer 131 has a thickness of 450 nm.

Sputtering to form non-crystalline AlOₓF_{y} layer 133 on the non-crystalline Al₂O₃ layer 131: the flow rate of Ar is 320 sccm, the flow rate of O₂ is 60 sccm; the CF₄ has a partial pressure of 0.45 Pa in the coating chamber 21; the substrate 11 has a negative bias voltage of −180 V; the aluminum targets 23 are applied with a radio frequency power at a power density of 55 W/cm²; the temperature inside of the coating chamber 21 is 200° C.; sputtering of the AlOₓF_{y} layer 133 takes 80 min; the value of ‘x’ within the AlOₓF_{y} is ‘0.5’, and the value of ‘y’ within the AlOₓF_{y} is ‘2’.

The contact angle between the anti-fingerprint film 13 and water-oil droplet is 112°.

### Example 2

Plasma cleaning the substrate 11: the flow rate of Ar is 350 sccm; the substrate 11 has a negative bias voltage of −450 V; plasma cleaning of the substrate 11 takes 10 min.

Sputtering to form non-crystalline Al₂O₃ layer 131 on the substrate 11: the flow rate of Ar is 450 sccm, the flow rate of O₂ is 450 sccm; the substrate 11 has a negative bias voltage of −220 V; the aluminum targets 23 are applied with an intermediate frequency power of 7 KW; the temperature inside of the coating chamber 21 is 390° C.; sputtering of the Al₂O₃ layer 131 takes 55 min; the Al₂O₃ layer 131 has a thickness of 600 nm.

Sputtering to form non-crystalline AlOₓF_{y} layer 133 on the non-crystalline Al₂O₃ layer 131: the flow rate of Ar is 450 sccm, the flow rate of O₂ is 150 sccm; the CF₄ has a partial pressure of 0.63 Pa in the coating chamber 21; the substrate 11 has a negative bias voltage of −220 V; the aluminum targets 23 are applied with a radio frequency power at a power density of 71 W/cm²; the temperature inside of the coating chamber 21 is 390° C.; sputtering of the AlOₓF_{y} layer 133 takes 100 min; the value of ‘x’ within the AlOₓF_{y} is ‘1’, and the value of ‘y’ within the AlOₓF_{y} is ‘1’.

The contact angle between the anti-fingerprint film 13 and water-oil droplet is 108°.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate; and
an anti-fingerprint film formed on the substrate;
wherein the anti-fingerprint film comprising a non-crystalline alumina layer formed on the substrate and a non-crystalline aluminum-oxygen-fluorine layer formed on the non-crystalline alumina layer, the aluminum-oxygen-fluorine has a chemical formula of AlOₓF_{y}, with 0<x<1.5, 0<y<3.

2. The coated article as claimed in claim 1, wherein the non-crystalline alumina layer has nano-dimensioned structures.

3. The coated article as claimed in claim 1, wherein the non-crystalline alumina layer has a thickness of about 450 nm-600 nm.

4. The coated article as claimed in claim 1, wherein the non-crystalline aluminum-oxygen-fluorine layer has nano-dimensioned structures.

5. The coated article as claimed in claim 4, wherein the non-crystalline aluminum-oxygen-fluorine layer defines a plurality of nano-dimensioned protruding particles thereon.

6. The coated article as claimed in claim 1, wherein the anti-fingerprint film is formed by magnetron sputtering.

7. The coated article as claimed in claim 1, wherein the substrate is made of metal selected from a group consisting of stainless steel, aluminum, aluminum alloy, copper, copper alloy, and zinc; or the substrate is made of ceramic, or glass.

8. The coated article as claimed in claim 1, wherein the anti-fingerprint film has a contact angle of about 108°-112° with water-oil droplets.

9. A method for making a coated article, comprising:
providing a substrate;
forming a non-crystalline alumina layer on the substrate by magnetron sputtering, using oxygen as a reaction gas and using aluminum target; and
forming a non-crystalline aluminum-oxygen-fluorine layer on the non-crystalline alumina layer by magnetron sputtering, using oxygen and carbon tetrafluoride as reaction gases and using aluminum target; the aluminum-oxygen-fluorine has a chemical formula of AlOₓF_{y}, with 0<x<1.5, 0<y<3.

10. The method as claimed in claim 9, wherein when forming the non-crystalline alumina layer the oxygen has a flow rate of about 200 sccm-500 sccm; the aluminum target is applied with a frequency power of 5 KW-10 KW; magnetron sputtering of the non-crystalline alumina layer uses argon as a working gas, the argon has a flow rate of about 300 sccm-500 sccm; vacuum sputtering of the non-crystalline alumina layer is conducted at a temperature of about 150° C.-420° C., vacuum sputtering of the non-crystalline alumina layer takes about 20 min-60 min.

11. The method as claimed in claim 10, wherein the substrate is biased with a negative bias voltage of about −150V to about −300V during vacuum sputtering of the non-crystalline alumina layer.

12. The method as claimed in claim 9, wherein when forming the non-crystalline aluminum-oxygen-fluorine layer the oxygen has a flow rate of about 50 sccm-200 sccm; the carbon tetrafluoride has a partial pressure of about 0.45 Pa-0.63 Pa; the aluminum target is applied with a radio frequency power having a power density of 50 W/cm²-100 W/cm²; magnetron sputtering of the aluminum-oxygen-fluorine layer uses argon as a working gas, the argon has a flow rate of about 300 sccm-500 sccm; vacuum sputtering of the non-crystalline aluminum-oxygen-fluorine layer is conducted at a temperature of about 150° C.-420° C., vacuum sputtering of the non-crystalline aluminum-oxygen-fluorine layer takes about 70 min-120 min.

13. The method as claimed in claim 12, wherein the substrate is biased with a negative bias voltage of about −150V to about −300V during vacuum sputtering of the non-crystalline aluminum-oxygen-fluorine layer.

14. The method as claimed in claim 9, further comprising a step of forming an aluminum transition layer on the substrate before forming the non-crystalline alumina layer.

15. The method as claimed in claim 14, further comprising a step of pre-treating the substrate before forming the aluminum transition layer.

16. The method as claimed in claim 15, wherein the pre-treating process comprising ultrasonic cleaning the substrate and plasma cleaning the substrate.

17. The method as claimed in claim 16, wherein plasma cleaning of the substrate uses argon as a working gas, the argon has a flow rate of about 300 sccm-500 sccm; the substrate is biased with a negative bias voltage of about −300 V to about −500 V; plasma cleaning of the substrate takes about 5 min-10 min.

18. The method as claimed in claim 9, wherein the substrate is made of metal selected from a group consisting of stainless steel, aluminum, aluminum alloy, copper, copper alloy, and zinc; or the substrate is made of ceramic, or glass.
